(19) United States
(12) Patent Application Publication
(10) Pub. No.: US 2017/0350038 A1
(43) Pub. Date: Dec. 7, 2017

(54) VACUUM PLATFORM WITH PROCESS CHAMBERS FOR REMOVING CARBON CONTAMINANTS AND SURFACE OXIDE FROM SEMICONDUCTOR SUBSTRATES

(71) Applicant: Applied Materials, Inc., Santa Clara, CA (US)

(72) Inventors: Kin Pong LO, Fremont, CA (US); Schubert S. CHU, San Francisco, CA (US)

(21) Appl. No.: 15/499,100

(22) Filed: Apr. 27, 2017

Related U.S. Application Data
(60) Provisional application No. 62/345,160, filed on Jun. 3, 2016.

(51) Int. Cl. C30B 25/18; H01L 21/67; C30B 29/06; H01L 21/02; C30B 29/52; H01L 21/677; C30B 25/20

(52) U.S. Cl. CPC C30B 25/186; H01L 21/67742; H01L 21/67207; H01L 21/67201; H01L 21/67196; H01L 21/67184; H01L 21/67167; C30B 25/20; H01L 21/0262; H01L 21/02532; H01L 21/02043; C30B 29/52; C30B 29/06; H01L 21/67028

(57) ABSTRACT

Implementations of the present disclosure generally relate to an improved vacuum processing system. In one implementation, the vacuum processing system includes a first transfer chamber coupling to at least one epitaxy process chamber, a second transfer chamber, a transition station disposed between the first transfer chamber and the second transfer chamber, a first plasma-cleaning chamber coupled to the second transfer chamber for removing oxides from a surface of a substrate, and a load lock chamber coupled to the second transfer chamber. The transition station connects to the first transfer chamber and the second transfer chamber, and the transition station includes a second plasma-cleaning chamber for removing carbon-containing contaminants from the surface of the substrate.

### CROSS-REFERENCE TO RELATED APPLICATIONS

This application claims priority to U.S. provisional patent application Ser. No. 62/345,160, filed Jun. 3, 2016, which is herein incorporated by reference.

### FIELD

Implementations of the present disclosure generally relate to an apparatus and a method for cleaning a surface of a substrate.

### BACKGROUND

Integrated circuits are formed in and on silicon and other semiconductor substrates. In the case of single crystal silicon, substrates are made by growing an ingot from a bath of molten silicon, and then sawing the solidified ingot into multiple substrates. An epitaxial silicon layer may then be formed on the monocrystalline silicon substrate to form a defect free silicon layer that may be doped or undoped. Semiconductor devices, such as transistors, may be manufactured from the epitaxial silicon layer. The electrical properties of the formed epitaxial silicon layer are generally better than the properties of the monocrystalline silicon substrate.

Surfaces of the monocrystalline silicon and the epitaxial silicon layer are susceptible to contamination when exposed to typical substrate fabrication facility ambient conditions. For example, a native oxide layer may form on the monocrystalline silicon surface prior to deposition of the epitaxial layer due to handling of the substrates and/or exposure to ambient environment in the substrate processing facility. Additionally, foreign contaminants such as carbon and oxygen species present in the ambient environment may deposit on the monocrystalline surface. The presence of a native oxide layer or contaminants on the monocrystalline silicon surface negatively affects the quality of an epitaxial layer subsequently formed on the monocrystalline surface. It is therefore desirable to pre-clean the substrates in order to remove the surface oxidation and other contaminants before epitaxial layers are grown on the substrates. However, pre-clean processes are often carried out in one or more standalone vacuum process chambers, which may increase substrate handling time and chances of exposing substrates to ambient environment.

Therefore, there is a need in the art to provide an improved substrate processing system for cleaning a substrate surface prior to performing an epitaxial deposition process that minimizes substrate handling time and exposure to ambient environment.

### SUMMARY

Implementations of the present disclosure generally relate to an improved vacuum processing system and a method for removing contaminants and native oxides from a surface of a substrate. In one implementation, the vacuum processing system includes a first transfer chamber coupled to at least one processing chamber, a second transfer chamber, a transition station disposed between, and connected to, the first transfer chamber and the second transfer chamber, the transition station comprising a first plasma-cleaning chamber, a second plasma-cleaning chamber coupled to the second transfer chamber, and a load lock chamber coupled to the second transfer chamber.

In another implementation, the vacuum processing system includes a first transfer chamber comprising a first substrate handling mechanism, a transition station coupled to the first transfer chamber, the transition station having a first plasma-cleaning chamber coupled to or disposed therein, and at least one process chamber coupled to the first transfer chamber, wherein the at least one process chamber is an epitaxy chamber.

In yet another implementation, a method for processing a substrate within a vacuum processing system is provided. The method includes transferring a substrate from a load lock chamber to a first cleaning chamber using a first robotic transport mechanism disposed within a first transfer chamber, the first cleaning chamber using a plasma formed from a cleaning gas comprising a hydrogen-containing gas and a fluorine containing gas to remove oxides from a surface of the substrate, transferring the substrate from the first cleaning chamber to a transition station by the first robotic transport mechanism, the transition station has a second cleaning chamber disposed therein, the second cleaning chamber using a hydrogen containing plasma to remove carbon-containing contaminants from the surface of the substrate, and transferring the substrate from the second cleaning chamber to at least an epitaxy process chamber coupled to a second transfer chamber using a second robotic transport mechanism disposed within the second transfer chamber, wherein the transition station is connected to the first transfer chamber and the second transfer chamber, and wherein the substrate is transferred among the load lock chamber, the first transfer chamber, the first cleaning chamber, the second cleaning chamber, the second transfer chamber, and the epitaxy process chamber without breaking vacuum in the vacuum processing system.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a processing sequence in accordance with one implementation of the present disclosure.

FIG. 2 is a cross-sectional view of a cleaning chamber used to perform a cleaning process of FIG. 1 in accordance with one implementation of the present disclosure.

FIG. 3 is a cross-sectional view of a cleaning chamber used to perform a reducing process of FIG. 1 in accordance with one implementation of the present disclosure.

FIG. 4 illustrates a vacuum processing system that can be used to complete the processing sequence of FIG. 1 according to implementations of the present disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

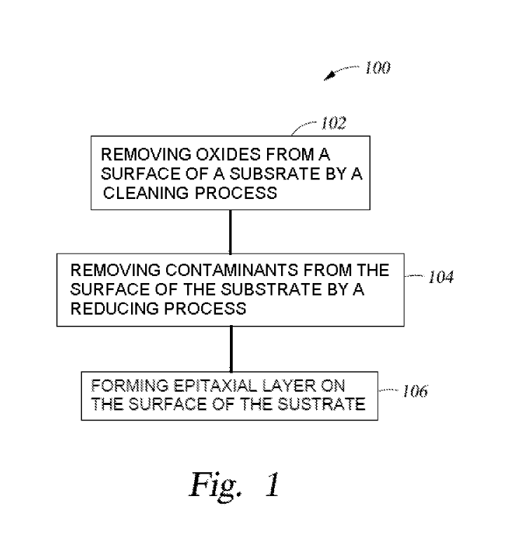

FIG. 1 illustrates a processing sequence 100 in accordance with one implementation of the present disclosure. In box 102, oxides are removed from a surface of a semiconductor substrate using a cleaning process. The substrate may include a silicon containing material and the surface may include a material, such as silicon (Si), germanium (Ge) or silicon germanium alloys (SiGe). In some implementations, the Si, Ge, or SiGe surface may have an oxide layer, such as a native oxide layer, and contaminants disposed thereon. Due to the sensitivity of epitaxial deposition processes to oxides and contaminants, such as carbon containing contaminants, surface contamination resulting from exposure to most typical cleanroom environments for a few hours can become significant enough for the accumulated oxides and contaminants to affect the quality of a subsequently formed epitaxial layer.

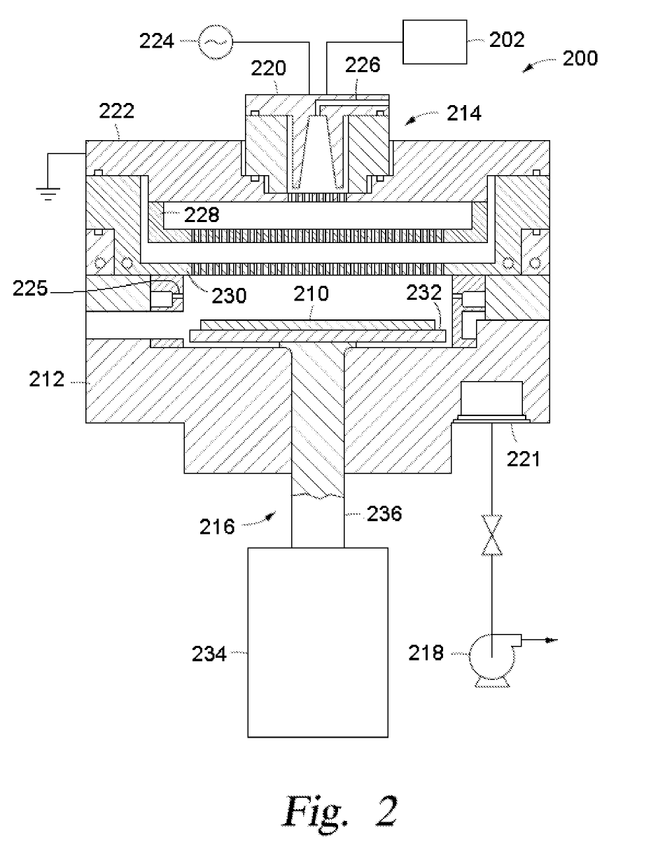

The substrate surface may be cleaned by performing an oxides removal process and a contaminant removal process. In one implementation, the oxides are removed from the surface of the substrate using a cleaning process (box 102), and the contaminants, such as carbon containing contaminants, are removed from the surface of the substrate using a reducing process (box 104). The cleaning process may include a plasma etching process. The plasma etching process may use a plasma formed form a cleaning gas including hydrogen (H₂), helium (He), argon (Ar), ammonia (NH₃), a fluorine containing gas such as NF₃, or any combination of these gases. The plasma may be inductively or capacitively coupled, or the plasma may be energized by a microwave source in a processing chamber. The processing chamber may be a remote plasma chamber that is spatially separated from a processing region in which the substrate is disposed. The term “spatially separated” described herein may refer to a plasma generation region that is separated from a substrate processing region by one or more chamber components such as a blocker plate 228 and a gas distribution plate 230 shown in FIG. 2, or even a conduit between a remote plasma chamber and a substrate processing chamber.

In one implementation, the plasma is generated using a capacitively coupled plasma source. Radicals from the plasma may pass through a gas distribution plate disposed above the substrate, which is positioned on a support at a temperature of about 25 degrees Celsius to about 100 degrees Celsius. The processing pressure may be at subatmospheric pressure, for example about 20 mTorr to about 25 mTorr. Radicals reach the substrate and then react with the surface oxides. Exemplary processing chambers that can be adapted to perform the plasma etching process include the Siconi™ or Selectra™ chambers, which are available from Applied Materials, Inc., of Santa Clara, Calif. Chambers from other manufacturers may also be used.

In one exemplary implementation, the plasma etch process is a remote plasma assisted dry etch process which involves the concurrent exposure of a substrate to NF₃ and NH₃ plasma by-products. In one example, the plasma etch process may be similar to or may include a SiCoNi™ etch process that is available from Applied Materials, Inc., of Santa Clara, Calif. The remote plasma etch can be largely conformal and selective towards silicon oxide layers, and thus does not readily etch silicon regardless of whether the silicon is amorphous, crystalline or polycrystalline. The remote plasma process will generally produce solid by-products which grow on the surface of the substrate as substrate oxide material is consumed. The solid by-products can be subsequently removed via sublimation when the temperature of the substrate is raised. The plasma etch process results in a substrate surface having silicon-hydrogen (Si—H) bonds thereon.

In box 104, after removing oxides from the surface of the substrate, any remaining contaminants on the surface of the substrate are removed. In one implementation of box 104, contaminants such as carbon or hydrocarbons are removed from the surface of the substrate using a reducing process. The reducing process may use a hydrogen containing plasma to remove contaminants. The plasma may be formed from a cleaning gas containing hydrogen gas (H₂), helium (He), argon (Ar), ammonia (NH₃), or any combination of these gases. The plasma may be inductively or capacitively coupled, or the plasma may be energized by a microwave source in a processing chamber. The processing chamber may be a remote plasma chamber that is physically separated from the processing chamber where the substrate is disposed.

In one implementation, the plasma is generated using an inductively coupled plasma source that is a remote plasma source (RPS) to perform the reducing process 104. Radicals from the plasma may pass through a passage tube and a gas distribution plate disposed above the substrate. The substrate is positioned on a support at a temperature of about 25 degrees Celsius to about 400 degrees Celsius. The processing pressure may be at subatmospheric pressure, for example about 20 mTorr to about 300 Torr, for example about 100 mTorr to about 300 mTorr, for example about 150 mTorr. Radicals reach the substrate and then react with the surface contaminants. Exemplary processing chambers that can be adapted to perform a reducing process include AKTIV Pre-Clean™, Siconi™, PCxT Reactive Preclean™ (RPC), or Selectra™ chambers, available from Applied Materials, Inc., of Santa Clara, Calif. Chambers from other manufacturers may also be used.

In box 106, an epitaxial layer is formed on the surface of the substrate. If cleaned prior, as described above, the surface of the substrate is oxide and contaminant free which improves the quality of the epitaxial layer subsequently formed on the surface of the substrate. An exemplary epitaxial process may be a selective epitaxial process performed at a temperature that is less than about 800 degrees Celsius, for example about 450 to 650 degrees Celsius. The epitaxial layer may be formed using a high temperature chemical vapor deposition (CVD) process. The epitaxial layer may be a crystalline silicon, germanium, or silicon germanium, or any suitable semiconductor material such as a Group III-V compound. In one exemplary thermal CVD process, processing gases such as dichlorosilane, silane, disilane, germane, hydrogen chloride, or combinations thereof are used to form the epitaxial layer. The processing temperature is under 800 degrees Celsius and the processing pressure is between 5 Torr and 600 Torr. An exemplary processing chamber that can be used to perform the epitaxial deposition process is the Centura™ Epi chamber, which is available from Applied Materials, Inc., of Santa Clara, Calif. Chambers from other manufacturers may also be used.

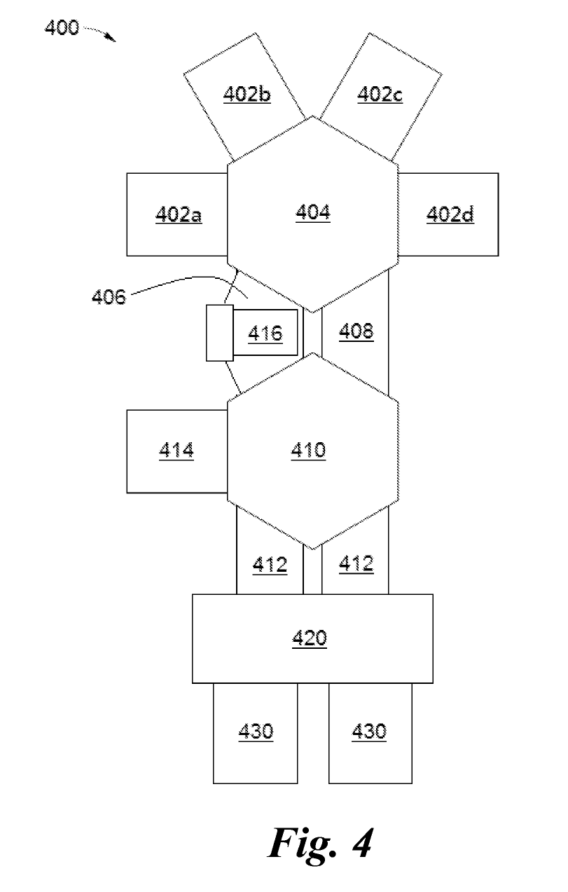

Boxes 102, 104 and 106 may be performed in one processing system, such as a vacuum processing system illustrated in FIG. 4. It is contemplated that processes described in boxes 102 and 104 may be reversed. In addition, the processes described in boxes 102 and 104 may be repeated as many times as necessary.

FIG. 2 is a cross sectional view of a processing chamber 200 that is adapted to perform at least some of the processes found in box 102, and thus removes oxides from a surface of a substrate. The processing chamber 200 may be particularly useful for performing a thermal or plasma-based cleaning process and/or a plasma assisted dry etch process. The processing chamber 200 includes a chamber body 212, a lid assembly 214, and a support assembly 216. The lid assembly 214 is disposed at an upper end of the chamber body 212, and the support assembly 216 is at least partially disposed within the chamber body 212. A vacuum system can be used to remove gases from processing chamber 200. The vacuum system includes a vacuum pump 218 coupled to a vacuum port 221 disposed in the chamber body 212. The processing chamber 200 also includes a controller 202 for controlling processes within the processing chamber 200.

The lid assembly 214 includes at least two stacked components configured to form a plasma volume or cavity. A first electrode 220 is disposed vertically above a second electrode 222 to define a plasma volume. The first electrode 220 is connected to a power source 224, such as a radio frequency (RF) power supply, and the second electrode 222 is connected to ground or a reference potential, forming a capacitance between the first electrode 220 and the second electrode 222. The lid assembly 214 also includes one or more gas inlets 226 for providing a cleaning gas to a substrate surface through a blocker plate 228 and a gas distribution plate 230, such as a showerhead. The cleaning gas may use radicals of a plasma formed form a cleaning gas including hydrogen (H₂), helium (He), argon (Ar), ammonia (NH₃), a fluorine containing gas such as NF₃, or any combination of these gases.

Alternatively, a different cleaning process may be utilized to clean the substrate surface. For example, a remote plasma containing He and NF₃ may be introduced into the processing chamber 200 through the gas distribution plate 230, while NH₃ may be directly injected into the processing chamber 200 via a separate gas inlet 225 that is disposed at a side of the chamber body 212.

The support assembly 216 may include a substrate support 232 to support a substrate 210 thereon during processing. The substrate support 232 may be coupled to an actuator 234 by a shaft 236 which extends through a centrally-located opening formed in a bottom of the chamber body 212. The actuator 234 may be flexibly sealed to the chamber body 212 by bellows (not shown) that prevent vacuum leakage around the shaft 236. The actuator 234 allows the substrate support 232 to be moved vertically within the chamber body 212 between a processing position and a loading position. The loading position is slightly below the opening of a slit valve formed in a sidewall of the chamber body 212.

The substrate support 232 has a flat, or a substantially flat, substrate supporting surface for supporting a substrate to be processed thereon. The substrate support 232 may be moved vertically within the chamber body 212 by actuator 234, which is coupled to the substrate support 232 by shaft 236. In operation, the substrate support 232 may be elevated to a position in close proximity to the lid assembly 214 to control the temperature of the substrate 210 being processed. As such, the substrate 210 may be heated via radiation emitted or convection from the distribution plate 230.

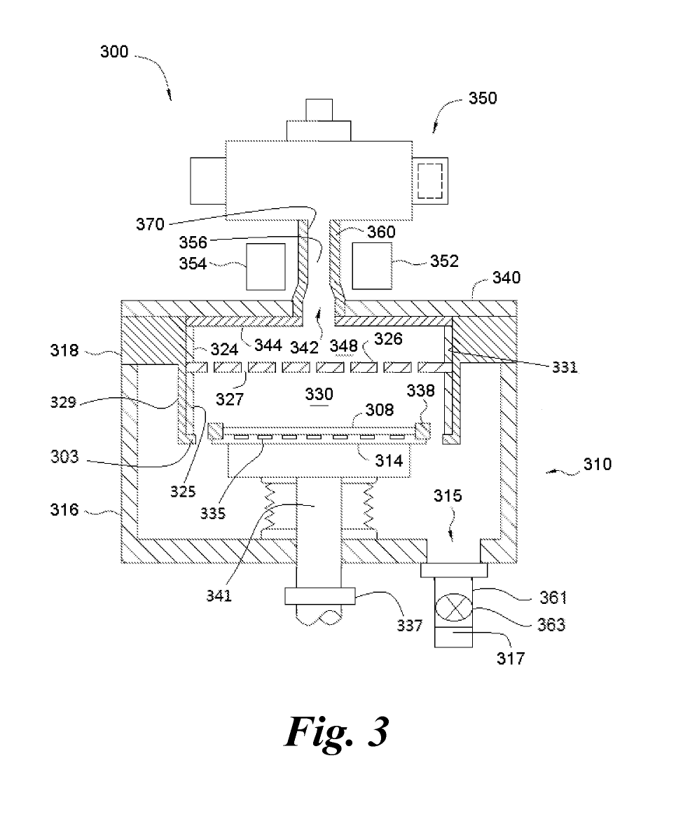

FIG. 3 is a cross sectional view of a processing chamber 300 that is adapted to perform at least some of the processes found in box 104, and thus removes contaminants, such as carbon or hydrocarbons accumulated on a surface of a substrate. The processing chamber 300 has a chamber body 310, which includes a chamber enclosure 316, a process kit housing 318, and a lid 340. The chamber enclosure 316 and the lid 340 may be fabricated from aluminum, stainless steel or other suitable materials. The process kit housing 318 may be fabricated from aluminum alloy or other suitable materials. The lid 340 is removably coupled to the chamber enclosure 316 through the process kit housing 318.

The process kit housing 318 may be a ring-shaped housing having a top surface that couples to the lid 340 and a bottom surface that couples to the chamber enclosure 316. The process kit housing 318 has a shield portion 329 extending down from an inner surface 331 of the process kit housing 318. The inner surface 331 of the process kit housing 318 surrounds and supports a gas distribution plate 326 thereon. The gas distribution plate 326 may be a quartz showerhead. A plenum 348 is defined between the gas distribution plate 326 and the lid 340. The gas distribution plate 326 includes a plurality of apertures 327 formed through the thickness of the gas distribution plate 326 to allow gases flowing into the plenum 348 through a port 342. The apertures 327 are evenly distributed across the diameter of the gas distribution plate 326 to ensure uniform distribution of the gases or radicals to the substrate 308. The gases flowing through the apertures 327 are distributed across the substrate 308 disposed in a process region 330 defined between the gas distribution plate 326 and a heater 314. The shield portion 329 also helps confine electrically neutral radicals within the process region 330. In one example, the shield portion 329 is extended to a location adjacent or below the edge of the heater 314.

The processing chamber 300 includes a remote plasma source 350 that is coupled to the port 342 by a passage tube 360. The port 342 is formed in the lid 340. The passage tube 360 defines a conduit 356, which may have a first inner diameter and a second inner diameter that is larger than the first inner diameter. The first inner diameter may be disposed adjacent to the remote plasma source 350 and the second inner diameter may be disposed adjacent to the lid 340. In one example, first inner diameter is about 12 mm to about 30 mm, for example about 20 mm, and the second inner diameter is about 35 mm to about 60 mm, for example about 40 mm.

The passage tube 360 is configured to filter ions generated in the remote plasma source 350 before entering the process region 330, while allowing electrically neutral radicals to enter the process region 330. The relative concentration of ions in the process region 330 is thus reduced. In one implementation, the gases flowing through the conduit 356 are filtered by a magnetic field generated by one or more magnets disposed adjacent to the passage tube 360. The magnets generate a magnetic field across the passage tube 360 to filter charged particles entrained with the reactive radicals flowing from the remote plasma source 350.

In the implementation depicted in FIG. 3, a first magnet 352 and a second magnet 354 are disposed adjacent to the passage tube 360. The first magnet 352 and second magnets 354 may be permanent magnets or electromagnets. The magnets 352, 354 may be disposed to oppose to each other across the first inner diameter of the passage tube 360. For example, the magnets 352, 354 may be adhered or secured on opposite sides of an outer periphery of the passage tube 360. It is also contemplated that the magnets 352, 354 may be secured to the chamber lid 340 or other components of the chamber body 310. The relative distance between the opposed magnet and the conduit 356 formed within the passage tube 360 affects the strength of the magnetic field passing through the conduit 356, and thereby affects the filtering efficiency. The magnetic field may also be adjusted by using different magnets, i.e., replacing magnets 352, 354 with different strength. The passing charged particles are drawn in contact with an inner surface 370 of the passage tube 360 and become electrically neutral, non-ionic species. As such, the filtered, electrically neutral radicals are delivered to the surface of the substrate to react with and clean contaminants thereon.

In some implementations, the ions may be further filtered by providing a quartz surface in the flow path of the process gases (i.e., radicals) passing into the chamber body 310. For example, the inner surface 370 of the passage tube 360 defining the conduit 356 may be entirely or partially coated or fabricated from quartz. Additionally, the surfaces defining the plenum 348 and/or gas distribution plate 326 may also be entirely or at least partially coated or fabricated from quartz. For example, in the implementation of FIG. 3, a top liner 324 may be disposed along the inner surface 331 of the process kit housing 318. The top liner 324 may have a ring-shaped body surrounding the plenum 348, an inner surface thereof defining the outer boundary of the plenum 348. The top liner 324 may be made of quartz. The top liner 324 may rest on the gas distribution plate 326, or may be supported by any other suitable securing approach.

A liner plate 344 may be disposed along the bottom surface of the lid 340. The liner plate 344 may be coated with, or fabricated from, quartz. The liner plate 344 defines the upper boundary of the plenum 348. Therefore, the liner plate 344, the top liner 324, and the gas distribution plate 326 define the plenum 348 therein. A bottom liner 325 may be disposed along the inner surface 331 of the process kit housing 318. The bottom liner 325 may have a ring-shaped body surrounding the process region 330, an inner surface thereof defining the outer boundary of the process region 330. The bottom liner 325 may be coated with, or fabricated from, quartz. The bottom liner 325 may be supported by the shield portion 329. In one example as shown, a ledge 303 extends radially inward at an end of the shield portion 329 to support the bottom liner 325. Therefore, the passage tube 360, the liner plate 344, the top liner 324, the bottom liner 325, and the gas distribution plate together provide a quartz surface in the flow path of the process gases. These components reduce the recombination of radicals as compared to other chamber materials (e.g., aluminum). As such, only electrically neutral radicals are flowed through the gas distribution plate or presented in a process region defined between the gas distribution plate and a substrate support of the processing chamber. These electrically neutral radicals will remain reactive when they reach and react with a surface of the substrate disposed on the substrate support the substrate to remove unwanted materials, for example native oxides, from the surface of the substrate

A heater (or substrate support) 314 is disposed in the process region 330 of the chamber body 310. The heater 314 is coupled to a bottom of the chamber enclosure 316 through a central shaft 341. The heater 314 has a substrate supporting surface for supporting the substrate 308 thereon during a process, such as the processes described above with respect to boxes 102 and 104. An optional focus ring 338 may be disposed on the heater 314 around the outer periphery of the substrate supporting surface. The focus ring 338 confines plasma or neutral species in an area above the substrate 308 during process. The focus ring 338 may be fabricated from quartz.

The heater 314 may be fabricated from bare aluminum with a plurality of sapphire contacts (not shown) disposed on the substrate supporting surface to minimize contact between the substrate supporting surface and a substrate disposed on the sapphire contacts. The heater 314 is actuated by a driving unit 337 to move vertically between a loading position and a processing position. The heater 314 may have one or more heating elements 335 embedded therein to provide uniform thermal energy to the substrate supporting surface. Suitable heating elements 335 may include resistive heaters, thermoelectric devices, or conduits for flowing heat transfer fluid, among other heating devices. The heating elements 335 allow the temperature of the substrate 308 to be maintained at a temperature range of about 200° C. to about 700° C., or greater, for example about 300° C. to about 350° C., about 350° C. to about 450° C., about 450° C. to about 550° C., about 550° C. to about 650° C., or about 650° C. to about 750° C. In some implementations, the heater 314 may have cutouts formed through the peripheral edge of the substrate supporting surface so that a substrate handler (not shown) can manipulate the substrate 308 from the edge of the substrate when the heater 314 is positioned at the loading position. During the cleaning process, the heater 314, with substrate 308 disposed thereon, is positioned at the processing position, which is a desired position for processing the substrate 308.

The processing chamber 300 includes a pump 317. The pump 317 is connected to the chamber body 310 through a foreline 361. The foreline 361 connects to the chamber body 310 at an opening 315 formed at the bottom of the enclosure 316. The chamber 300 also includes a throttle valve 363 disposed in the foreline 361. The throttle valve 363 is operated to open and close to whatever extent is necessary to maintain the pressure in the processing chamber 300 in a desired vacuum range for the plasma cleaning process being run. The pump 317 and the throttle valve 363 control the pressure inside the chamber body 310 from between about 0.005 Torr and 750 Torr, for example about 40 Torr to about 500 Torr. In one example, the pump 317 is a dry pump that maintains the pressure inside the processing chamber 300 at an exemplary pressure range of about 0.1 Torr to about 40 Torr, for example about 30 Torr. In one example, the pump 317 is a low pressure pump that maintains the pressure inside the processing chamber 300 at an exemplary pressure range of about 100 mTorr to about 500 mTorr, for example about 150 mTorr. In some examples, the pump 317 is a turbo pump that maintains the pressure inside the processing chamber 300 at an exemplary pressure range of about 20 mTorr to 50 mTorr.

FIG. 4 illustrates an exemplary vacuum processing system 400 that can be used to complete the processing sequence 100 illustrated in FIG. 1, according to implementations of the present disclosure. As shown in FIG. 4, a plurality of processing chambers 402a, 402b, 402c, 402d are coupled to a first transfer chamber 404. The processing chambers 402a-402d may be used to perform any substrate related processes, such as annealing, chemical vapor deposition, physical vapor deposition, epitaxial process, etching process, thermal oxidation or thermal nitridation process, degassing etc. In one implementation, the processing chamber 402a may be an epitaxy deposition chamber, for example a Centura˜ Epi chamber available from Applied Materials, Santa Clara, Calif., that is capable of forming a crystalline silicon or silicon germanium. The processing chamber 402b may be a rapid thermal processing chamber (RTP). The processing chamber 402c is a plasma etching chamber. The processing chamber 402d may be a degassing chamber. The first transfer chamber 404 is also coupled to at least one transition station, for example a pair of pass-through stations 406, 408. The pass-through stations 406, 408 maintain vacuum conditions while allowing substrates to be transferred between the first transfer chamber 404 and a second transfer chamber 410. The first transfer chamber 404 has a robotic substrate handling mechanism (not shown) for transferring substrates between the pass-through stations 406, 408 and any of the processing chambers 402a-402d.

One end of the pass-through stations 406, 408 is coupled to the second transfer chamber 410. Therefore, the first transfer chamber 404 and the second transfer chamber 410 are separated and connected by the pass-through stations 406, 408. The second transfer chamber 410 is coupled to a first plasma-cleaning chamber 414, which can be a plasma chamber such as the processing chamber 200 (FIG. 2) that is adapted to perform at least some of the processes found in box 102 for removing oxides from a surface of a substrate. In one implementation, the first plasma-cleaning chamber 414 is a Siconi™ or Selectra™ chamber, which is available from Applied Materials, Santa Clara, Calif.

In one implementation, the at least one transition station, for example one of the pass-through stations 406, 408, is configured to be a plasma-cleaning chamber. Alternatively, a plasma-cleaning chamber may be coupled to one of the pass-through stations 406, 408 for removing contaminants from the surface of the substrate. Thus, the processing system 400 may have a second plasma-cleaning chamber that is, or is connected to, one of the pass-through stations 406, 408. In one implementation shown in FIG. 4, the pass-through station 406 includes a second plasma-cleaning chamber 416. The second plasma-cleaning chamber 416 may be a version of the processing chamber 300 (FIG. 3) that is adapted to perform at least some of the processes found in box 104 for removing contaminants from the surface of the substrate. It should be noted that, although only one plasma-cleaning chamber 416 is shown coupled to a pass-through station, in this case the pass-through station 406, a plasma-cleaning chamber (e.g., a version of the processing chamber 300) may be coupled to both the pass-through stations 406 and 408.

The second transfer chamber 410 also has a robotic substrate handling mechanism (not shown) for transferring substrates between a set of load lock chamber 412 and the first plasma-cleaning chamber 414 or the second plasma-cleaning chamber 416. A factory interface 420 is connected to the second transfer chamber 410 by the load lock chambers 412. The factory interface 420 is coupled to one or more pods 430 on the opposite side of the load lock chambers 412. The pods 430 typically are front opening unified pods (FOUP) that are accessible from a clean room (not shown).

While two transfer chambers are shown, it is contemplated that any of the transfer chambers may be omitted. In one implementation where the second transfer chamber 410 is omitted, the second plasma-cleaning chamber 416 may be disposed within or coupled to the first transfer chamber 404 at the loation currently shown as occupied by the pass-through stations 406 or 408. The first transfer chamber 404 may be coupled to one or more processing chambers capable of forming crystalline silicon or silicon germanium, such as an epitaxy chamber, for example a Centura™ Epi chamber available from Applied Materials, Inc., of Santa Clara, Calif. Alternatively, the first transfer chamber 404 may be omitted and the second plasma-cleaning chamber 416 may be disposed within or coupled to the pass-through station 406, which is coupled to the second transfer chamber 410. In such a case, the second transfer chamber 410 may be configured to be coupled to one or more processing chambers capable of forming crystalline silicon or silicon germanium.

In operation, substrates are carried from pods 430 to the vacuum processing system 400 in a transport cassette (not shown) that is placed within one of the load lock chambers 412. The robotic transport mechanism within the second transfer chamber 410 transports the substrates, one at a time, from the load lock chambers 412 to the first plasma-cleaning chamber 414 where the a cleaning process, e.g., processes found in box 102, is performed to remove oxides from a surface of a substrate. Once the oxides have been removed from the substrate surface, the robotic transport mechanism disposed within the second transfer chamber 410 transfers the substrate from the first plasma-cleaning chamber 414 to the second plasma-cleaning chamber 416 where a reducing process, e.g., processes found in box 104, is performed to remove contaminants such as carbon or hydrocarbons from the substrate surface. It is contemplated that the steps here may also be performed in the reverse order, i.e., using the robotic transport mechanism to transfer the substrate from the second plasma-cleaning chamber 416 to the first plasma-cleaning chamber 414. In either case, the clean substrates are then transferred by the robotic transport mechanism disposed within the first transfer chamber 404 from the second plasma-cleaning chamber 416 (or the first plasma-cleaning chamber 414) to one or more processing chambers 402a-402d. The one or more processing chambers 402a-402d may include an epitaxy process chamber where a layer formation process, such as the epitaxial deposition described in box 106, is performed.

Upon completion of processing in the one or more processing chambers 402a-402d, the robotic transport mechanism disposed within the first transfer chamber 404 moves the substrate from either one of the processing chambers 402 to the pass-through station 408. The substrate is then removed from the pass-through station 408 by the robotic transport mechanism disposed within the second transfer chamber 410 and transferred to the other load lock chamber 412 through which it is withdrawn from the vacuum processing system 400.

Since the processes of all three boxes 102, 104 and 106 are performed within the same vacuum processing system 400, vacuum is not broken as the substrate is transferred among various chambers, which decreases the chance of contamination and improves the quality of the deposited epitaxial film. It should be understood that the movement of the substrates is described herein for illustration purposes. A controller (not shown) may be used to schedule the movement of the substrates through the vacuum processing system 400 in accordance with a desired sequencing program, which may vary depending upon the application.

Benefits of the present disclosure include an improved vacuum processing system integrating two different types of pre-clean process chambers with the epitaxial process chamber on the same vacuum processing system. The pre-clean process chambers may include a first plasma-cleaning process chamber and a second plasma-cleaning process chamber. Co-existence of two types of surface materials removal chamber on the same vacuum processing system allows substrates to remain in vacuum between surface preparation and epitaxial deposition, which reduces the time the substrates are exposed to ambient and eliminates the need to prepare the substrates on a separate processing chamber or system. This architecture also maximizes the number of process chambers on a vacuum system because the pass-through station between two transfer chambers also functions as a pre-clean process chamber, which also reduces overall handling time of the substrates.

While the foregoing is directed to implementations of the present disclosure, other and further implementations of the disclosure may be devised without departing from the basic scope thereof.

1. A vacuum processing system, comprising:
a first transfer chamber coupled to at least one processing chamber;
a second transfer chamber;
a transition station disposed between, and connected to, the first transfer chamber and the second transfer chamber, the transition station comprising a first plasma-cleaning chamber;
a second plasma-cleaning chamber coupled to the second transfer chamber; and
a load lock chamber coupled to the second transfer chamber.

2. The vacuum processing system of claim 1, wherein the first plasma-cleaning chamber comprises an inductively coupled plasma source.

3. The vacuum processing system of claim 1, wherein the first plasma-cleaning chamber comprises:
a chamber body having a chamber enclosure enclosing a substrate support, wherein the substrate support comprises one or more heating elements;
a driving unit coupled to the substrate support to move the substrate support vertically;
a remote plasma source;
a passage tube coupling the remote plasma source to the chamber body;
at least one magnet disposed adjacent to the passage tube;
a gas distribution plate disposed within the chamber body, wherein the gas distribution plate has a plurality of apertures formed through the thickness of the gas distribution plate, and the gas distribution plate and the substrate support define a first plenum therebetween;
a pump coupled to the chamber enclosure; and
a throttle valve disposed between the pump and the chamber enclosure.

4. The vacuum processing system of claim 3, wherein the one or more heating elements are capable of heating an object to a temperature range of about 450° C. to about 650° C.

5. The vacuum processing system of claim 3, wherein an inner surface of the passage tube is coated with, or fabricated from, quartz.

6. The vacuum processing system of claim 3, wherein the pump and the throttle valve are capable of maintaining the pressure inside the first plasma-cleaning chamber at a pressure range of about 0.005 Torr to about 500 Torr during a process.

7. The vacuum processing system of claim 3, wherein the chamber body further comprises:
a lid;
a liner plate disposed along a bottom surface of the lid, wherein the liner plate is coated with, or fabricated from, quartz;
a process kit housing disposed between the lid and the chamber enclosure, wherein an inner surface of the process kit housing supports the gas distribution plate;
a top liner disposed along the inner surface of the process kit housing, wherein the top liner is coated with, or fabricated from, quartz, and the top liner, the liner plate, and the gas distribution plate defines a second plenum therein; and
a bottom liner disposed to the inner surface of the process kit housing, wherein the bottom liner is coated with, or fabricated from, quartz, and the bottom liner circumscribes an outer boundary of the first plenum.

8. The vacuum processing system of claim 1, wherein the second plasma-cleaning chamber comprises a capacitively coupled plasma source.

9. The vacuum processing system of claim 1, wherein the second plasma-cleaning chamber further comprises:
a chamber body;
a lid assembly coupled to the chamber body, the lid assembly comprising two electrodes defining a plasma volume therebetween;
a substrate support disposed in the chamber body;
a gas distribution plate disposed between the lid assembly and the substrate support; and
a vacuum pump coupled to the chamber body.

10. The vacuum processing system of claim 1, wherein the transition station comprises a first pass-through station and a second pass-through station, and the first plasma-cleaning chamber is disposed within the first pass-through station.

11. The vacuum processing system of claim 1, wherein the transition station comprises a first pass-through station and a second pass-through station, and the first plasma-cleaning chamber is coupled to the first pass-through station.

12. The vacuum processing system of claim 1, wherein at least one processing chamber is an epitaxy process chamber.

13. A vacuum processing system, comprising:
a first transfer chamber comprising a first substrate handling mechanism;
a transition station coupled to the first transfer chamber, the transition station having a first plasma-cleaning chamber coupled to or disposed therein; and
at least one process chamber coupled to the first transfer chamber, wherein the at least one process chamber is an epitaxy chamber.

14. The vacuum processing system of claim 13, wherein the first plasma-cleaning chamber comprises:
a chamber body having an enclosure enclosing a substrate support, wherein the substrate support comprises one or more heating elements;
a driving unit coupled to the substrate support to move the substrate support vertically;
a remote plasma source;
a passage tube coupling the remote plasma source to the chamber body;
at least one magnet disposed adjacent to the passage tube;
a gas distribution plate disposed within the chamber body, wherein the gas distribution plate has a plurality of apertures formed through the thickness of the gas distribution plate, and the gas distribution plate and the substrate support define a first plenum therebetween; and
a pump coupled to the chamber body.

15. The vacuum processing system of claim 14, wherein the heating elements are capable of heating an object to a temperature range of about 450° C. to about 550° C. or about 550° C. to about 650° C.

16. The vacuum processing system of claim 13, wherein the epitaxy chamber is capable of forming a crystalline silicon or silicon germanium.

17. The vacuum processing system of claim 13, further comprising:
a second transfer chamber coupled to the first transfer chamber and the transition station, the second transfer chamber comprising a second substrate handling mechanism;
a second plasma-cleaning chamber coupled to the second transfer chamber; and
a load lock chamber coupled to the second transfer chamber.

18. The vacuum processing system of claim 17, wherein the second plasma-cleaning chamber further comprising:
a chamber body enclosing a substrate support, wherein the substrate support has a substrate supporting surface;
a lid assembly, comprising:
a first electrode; and
a second electrode, wherein the first electrode is disposed vertically above the second electrode, the first and second electrodes defining a plasma volume therebetween;
a gas distribution plate disposed between the lid assembly and the substrate support; and
a pump coupled to the chamber body.

19. The vacuum processing system of claim 13, further comprising:
a rapid thermal processing chamber coupled to the first transfer chamber;
a plasma etching chamber coupled to the first transfer chamber; and
a degassing chamber coupled to the first transfer chamber.

20. A method for processing a substrate within a vacuum processing system, comprising:
transferring a substrate from a load lock chamber to a first cleaning chamber using a first robotic transport mechanism disposed within a first transfer chamber, the first cleaning chamber using a plasma formed from a cleaning gas comprising a hydrogen-containing gas and a fluorine containing gas to remove oxides from a surface of the substrate;
transferring the substrate from the first cleaning chamber to a transition station by the first robotic transport mechanism, the transition station has a second cleaning chamber disposed therein, the second cleaning chamber using a hydrogen containing plasma to remove carbon-containing contaminants from the surface of the substrate; and
transferring the substrate from the second cleaning chamber to at least an epitaxy process chamber coupled to a second transfer chamber using a second robotic transport mechanism disposed within the second transfer chamber, wherein the transition station is connected to the first transfer chamber and the second transfer chamber, and
wherein the substrate is transferred among the load lock chamber, the first transfer chamber, the first cleaning chamber, the second cleaning chamber, the second transfer chamber, and the epitaxy process chamber without breaking vacuum in the vacuum processing system.
